(19) United States
(12) Patent Application Publication
(10) Pub. No.: US 2009/0172235 A1
(43) Pub. Date: Jul. 2, 2009

(54) MEGASIM CARD ADAPTER

(76) Inventors: Mei Yan, Cupertino, CA (US); Robert C. Chang, Danville, CA (US); Patricia Ann Dwyer, San Carlos, CA (US); Po Yuan, Milpitas, CA (US); Bahman Qawami, San Jose, CA (US); Farshid Sabet-Sharghi, Los Altos Hills, CA (US); Fabrice J. Jogand-Coulomb, San Carlos, CA (US); Matthijs C. Hutten, Redwood City, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/965,704

(22) Filed: Dec. 27, 2007

(51) Int. Cl. H05K 7/10; H01R 31/06

(52) U.S. Cl. 710/302; 439/628

(57) ABSTRACT

A MegaSIM adapter is disclosed allowing a MegaSIM card to be used in a standard card slot, such as an SD or MicroSD card slot, of a host device.

### BACKGROUND OF THE INVENTION

1. Field of the Invention

Embodiments of the present invention relate to an adapter for adapting a MegaSIM card to other standard memory card slots.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

One type of card traditionally used for mobile cellular telephony devices such as mobile computers and mobile phones is a SIM (Subscriber Identity Module) card. SIM cards feature cryptographic functionality for securely storing network identification and authentication information, such as for example the service-subscriber key (IMSI). One advantage of the SIM card is that it allows users to change phones by simply removing the SIM card from one mobile phone and inserting it into another mobile phone or broadband telephony device. However, traditional SIM cards suffer from limited storage capacity (on the order of 64-256 kilobytes), and as such are not equipped to handle general purpose mass storage of multimedia files or applications.

Moreover, traditional SIM cards operate by slow speed data transfer protocols. The International Standard Organization (ISO) publishes mechanical and electrical specifications used for SIM cards. One such specification, the ISO 7816 group of standards, relates to the data transfer protocols used by traditional SIM cards. While data transfer rates per this specification are satisfactory for the small amount of data transferred in traditional SIM cards, it would be unduly slow for the transfer of the large amounts of data stored on high capacity memory devices.

These disadvantages have led to the development of the MegaSIM card. Unlike its predecessor, the MegaSIM card includes high capacity flash memory-based storage on the order of 128 MB to 2 GB or higher, thus making it useful as a general purpose multimedia storage device. Moreover, in addition to being compatible with the legacy ISO data transfer standard, the MegaSIM card also operates by high speed data protocols, such as the MMC (MultiMedia Card) and USB (Universal Serial Bus) interfaces.

A known configuration for a MegaSIM card 20 is shown in prior art FIG. 1. As in prior generation SIM cards, the MegaSIM card 20 may include a SIM controller 22 and an ISO 7816 interface 24. The SIM controller 22 may include storage, for example an EEPROM, on which may be stored encrypted network authentication and identification information and other data. However, the MegaSIM card 20 may further include flash storage 26, typically NAND-based with for example 2 GB capacity, a high-speed interface 28, such as USB or MMC, used for data transfer between the flash storage and a host device, and a flash controller 30 to handle the data transfer to/from the flash storage and the host device. In some MegaSIM configurations, SIM data may be stored within the flash memory 26, with security of such data controlled by the SIM controller 22.

In traditional SIM cards, signals were transferred through the ISO 7816 interface 24 via an eight pin connector, such as connector 40 shown in prior art FIG. 2. Generally only five of pins are used for signal transfer—one each for data (I/O), clock (CL), reset (RS), power (VD) and ground signals (GN). The MegaSIM card 20 may use the same pin connector as that for traditional SIM cards. Such a connector 44 is shown in prior art FIG. 3. The communication of SIM data from SIM controller 22 to a host device may take place through the ISO 7816 interface, using the same five pins as in a traditional SIM card. High speed data transfer to and from flash memory 26 may take place through the USB interface 28 via a pair of additional connector pins 46 and 48 that are traditionally not used in SIM cards. It is possible that the standard MegaSIM connector layout may change in the future, for example to add more pins or to change some pin functions for higher speed.

Given the advantages of the MegaSIM card, it may be desirable to use a MegaSIM card as a general purpose mass storage device for users to store multimedia files and applications in addition to the traditional SIM information. However, the MegaSIM interface is rarely included in host devices outside of mobile phone or broadband telephony devices, and thus, at present, most devices cannot operate with the MegaSIM card. It is known to provide a USB adapter which works with the older SIM cards. However, such adapters use the older connector, and are unable to access or transfer data to or from the flash memory of the newer MegaSIM cards. There is therefore a need to allow use of the MegaSIM card with other, more commonly deployed memory card standards such as for example SD (Secure Digital) and MicroSD cards.

### SUMMARY OF THE INVENTION

Embodiments of the present invention relate to a MegaSIM adapter allowing a MegaSIM card to be used in a standard card slot, such as an SD or MicroSD card slot, of a host device. In embodiments of the adapter used within an SD card slot, the adapter may have a size and form factor matching a standard SD card. The interior of the adapter may include an integrated circuit assembly including a connector configured to mate with the connector on the MegaSIM card, and contact fingers configured as standard contact fingers in an SD card.

Once a MegaSIM card is inserted into the MegaSIM adapter, the adapter allows the exchange of data between the MegaSIM card and a host device, such as for example a PC, digital camera, digital music player, video game console, PDA and/or cellular telephone. Many conventional adapters are provided to adapt memory cards of different sizes that operate by the same protocols, such as for example an adapter adapting a MicroSD card to work within an SD card slot. These adapters need only include an internal network of electrical traces and terminals to connect the contact fingers of the inserted card to the contact fingers of the adapter that mate with the electrical terminals within the host slot. However, MegaSIM cards operate by USB protocols, which are different than the SD protocols. Accordingly, the integrated circuit assembly of the MegaSIM adapter further includes a microcontroller for transferring between the MegaSIM card and SD card protocols.

A further embodiment of the present invention relates to a MegaSIM adapter capable of operating within a MicroSD card slot. In such an embodiment, the adapter may be formed with a connector protruding from a lid. The connector may be formed in the shape of a MicroSD card so that the connector may fit within a standard MicroSD card slot. The remaining portions of the adapter may protrude from the card slot. The connector may be formed on the same substrate as the integrated circuit assembly in this embodiment, so that the connector is stationary with respect to the lid. In an alternative embodiment, the connector may be flexibly mounted with respect to the lid, as for example by a flex cable. In a further embodiment, the connector may be movable between a first position retracted within the lid and a second, extended position for receipt within a MicroSD card slot.

### DESCRIPTION OF THE DRAWINGS

FIG. 1 is a prior art block diagram of a MegaSIM card.

FIG. 2 is a prior art illustration of a SIM connector.

FIG. 3 is a prior art illustration of a MegaSIM connector.

FIG. 4 is a top view of a MegaSIM adapter configured per the SD card standard, for receiving a MegaSIM card.

FIG. 5 is a top view of a substrate including an integrated circuit assembly of the MegaSIM adapter according to the present invention.

FIG. 6 is a flowchart showing the fabrication of a MegaSIM adapter according to the embodiments of the present invention.

FIG. 7 is a top view of a MegaSIM adapter according to the embodiments of the present invention including a MegaSIM card inserted therein.

FIG. 8 is an end view of a MegaSIM adapter according to embodiments of the present invention including a slot for receiving a MegaSIM card.

FIGS. 9 and 10 are side views of embodiments of the present invention including a cap for sealing a MegaSIM card within a MegaSIM adapter.

FIGS. 11 and 12 are top and side views of a MegaSIM adapter including a door on a top surface of the adapter according to an alternative embodiment of the present invention.

FIG. 13 is a block diagram showing a MegaSIM card within a MegaSIM adapter according to an embodiment of the present invention.

FIG. 14 is a top view of a MegaSIM adapter for receiving a MegaSIM card according to an alternative embodiment configured to operate within a MicroSD card slot.

FIG. 15 is a top view of an integrated circuit assembly on a substrate for use within the MegaSIM adapter of FIG. 12.

FIG. 16 shows a MegaSIM adapter for use within a MicroSD card slot according to an alternative embodiment of the present invention.

FIGS. 17-22 show a MegaSIM adapter for use with a MicroSD card slot according to a further alternative embodiment of the present invention including a retractable connector.

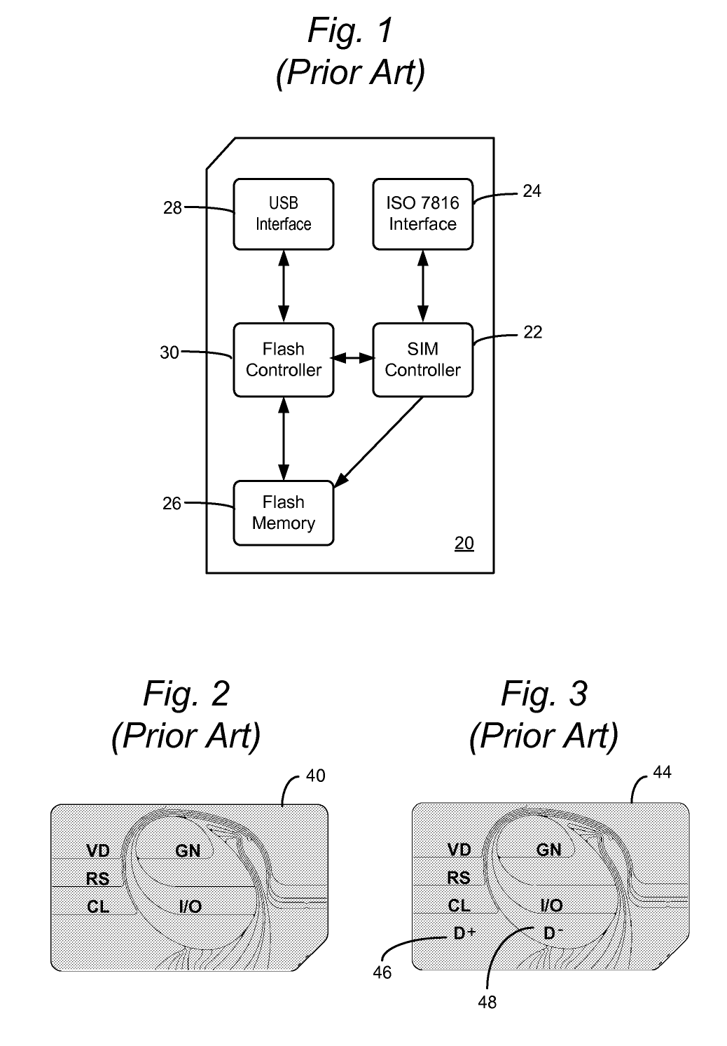

### DETAILED DESCRIPTION

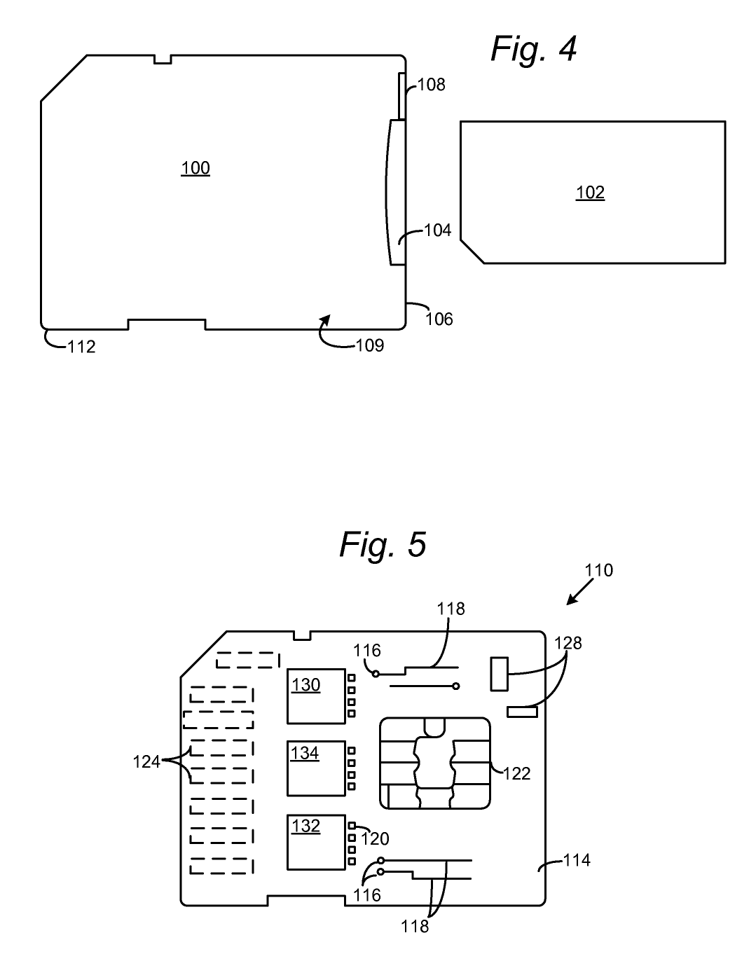

Embodiments will now be described with reference to FIGS. 4-22, which relate to adapters allowing use of a MegaSIM card with standard flash memory card interfaces. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

Referring initially to FIG. 4, there is shown a MegaSIM adapter 100 allowing use of a conventional MegaSIM card 102 with a standard SD (Secure Digital) interface. Thus, the MegaSIM adapter 100 shown in FIG. 4 may have the same form factor and shape as a conventional SD card. The adapter 100 may additionally include a slot 104 at a rear edge 106 for receiving the MegaSIM card 102. In embodiments, a slide 108 may be used to secure the MegaSIM card within the adapter 100 as described in greater detail hereinafter.

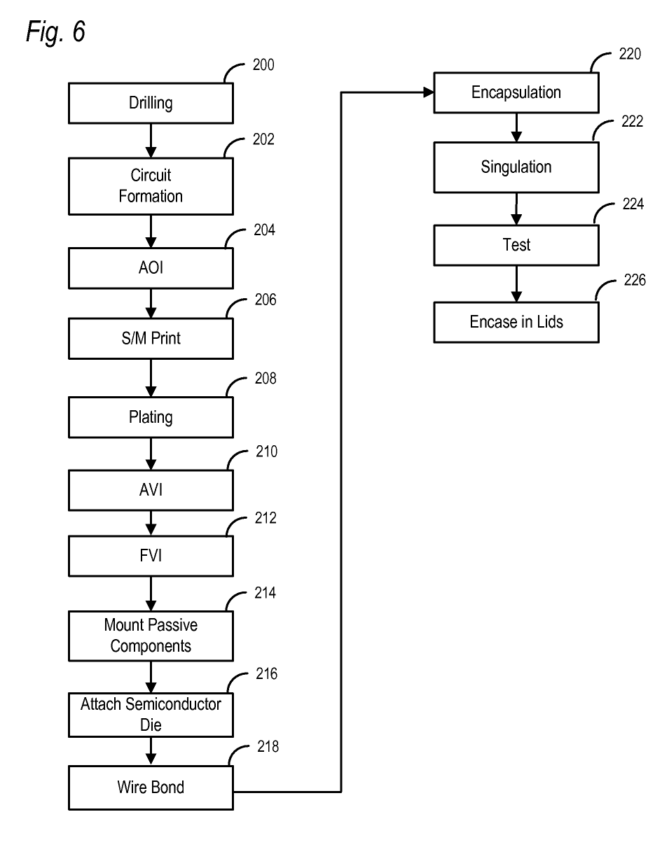

In general, MegaSIM adapter 100 includes an integrated circuit assembly 110 (FIG. 5) encased within a lid 112 (FIG. 4). The fabrication of the integrated circuit assembly 110 of FIG. 3 will now be described with reference to the flowchart of FIG. 6. Although FIG. 5 shows an individual integrated circuit assembly 110, it is understood that the integrated circuit assembly 110 may be batch processed along with a plurality of other integrated circuit assemblies 110 on a substrate panel to achieve economies of scale.

The substrate panel begins with a plurality of substrates 114 such as substrate 114 shown in FIG. 5. The substrate 114 may be a variety of different chip carrier mediums, including a printed circuit board (PCB), a leadframe or a tape automated bonded (TAB) tape. Where substrate 114 is a PCB, the substrate may be formed of a core having a top conductive layer and a bottom conductive layer. The core may be formed of various dielectric materials such as for example, polyimide laminates, epoxy resins including FR4 and FR5, bismaleimide triazine (BT), and the like. The conductive layers surrounding the core may be formed of copper or copper alloys, plated copper or plated copper alloys, Alloy 42 (42Fe/58Ni), copper plated steel, or other metals and materials known for use on substrate panels.

Referring now to the flowchart of FIG. 6, in a step 200, the substrate 114 is drilled to define through-hole vias 116 in the substrate 114. The vias 116 shown are by way of example, and the substrate 114 may include many more vias 116 than are shown in the figures, and they may be in different locations than are shown in the figures. Conductance patterns are next formed on one or both of the top and bottom conductive layers in step 202. The conductance pattern(s) may include electrical traces 118 and contact pads 120. The traces 118 and contact pads 120 shown are by way of example, and the substrate 114 may include more traces and/or contact pads than are shown in the figures, and they may be in different locations than are shown in the figures. The conductance pattern on the top and bottom surfaces of the substrate 114 may be formed by a variety of known processes, including for example various photolithographic processes.

The adapter 100 further includes a MegaSIM connector 122 defined in the conductance pattern, and contact fingers 124 (on a side of substrate 114 opposite connector 122 and shown in phantom). The MegaSIM connector 122 is provided to mate with the MegaSIM connector on MegaSIM card 102 upon insertion of the card 102 into adapter 100. Accordingly, connector 122 may be defined with the same number and configuration of pins as on the MegaSIM card 102. Different MegaSIM cards may have different configurations of pins in their connector. Accordingly, MegaSIM adapter 100 may have different configurations of pins in its connector 122. The particular configuration of pins shown in FIG. 5 is by way of example. It is possible that the standard MegaSIM connector layout may change in the future, for example to add more pins or to change some pin functions for higher speed. The number of pins on connector 122 may change accordingly to match any change in the standard MegaSIM connector. Contact fingers 124 are the same as the contact fingers that are found in a conventional SD card. Fingers 124 would mate with contact terminals within a host device (not shown) to enable communication between the host device and MegaSIM card 102 within the adapter 100.

Referring again to FIG. 6, after the conductance pattern is formed, the substrate 114 may be inspected in an automatic optical inspection (AOI) in step 204. Once inspected, a solder mask may be applied to the substrate in step 206. After the solder mask is applied, the contact pads 120, connector 122, contact fingers 124 and any other solder areas on the conductance patterns may be plated with a Ni/Au, Alloy 42 or the like in step 208 in a known electroplating or thin film deposition process. The substrate 114 may then be inspected and tested in an automated inspection process (step 210) and in a final visual inspection (step 212) to check electrical operation, and for contamination, scratches and discoloration. Assuming the substrate 114 passes inspection, passive components 128 may next be affixed to the substrate in a step 214. The one or more passive components 128 may include for example one or more capacitors, resistors and/or inductors, though other components are contemplated.

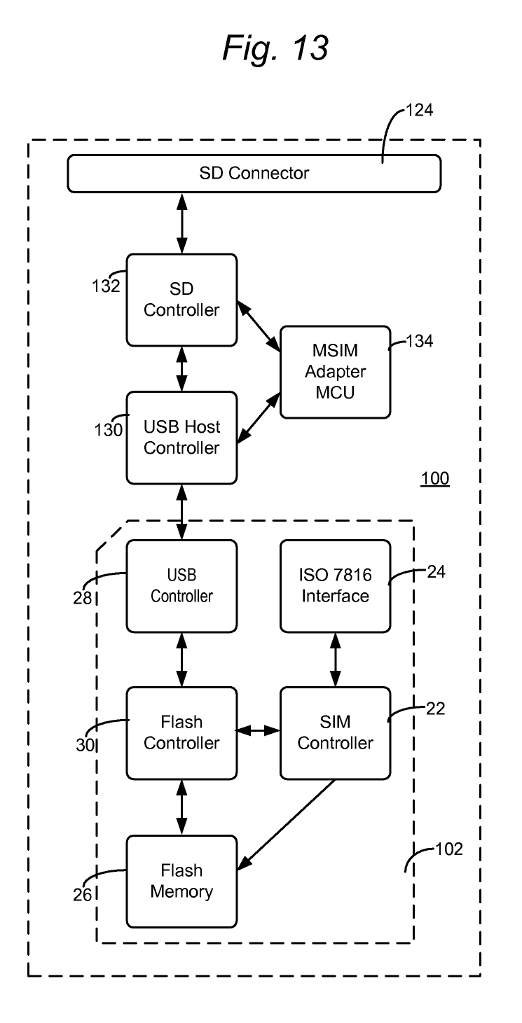

In step 216, the semiconductor die may be mounted to the substrate 114, and electrically coupled in a step 218. As explained in greater detail below with respect to FIG. 13, the semiconductor die mounted to the substrate 114 may include a USB host controller die 130, an SD controller die 132, and an adapter microcontroller die 134 for communicating between controllers 130 and 132. The die 130, 132 and 134 may be affixed to substrate 114 in step 216 in a known die attach process. The die 130, 132 and 134 may be electrically coupled to substrate 114 in step 218 by a known process such as wire bonding, TSOP surface mounting, flip chip bonding or the like. It is understood that the positions of the respective die 130, 132 and 134 shown in FIG. 5 is by way of example only. The die may be arranged in other configurations, and two or more of die 130, 132 and 134 may be stacked in further embodiments.

Although substrate 114 is sealed within lid 112, the substrate 114 may be encapsulated in a mold compound in a step 220. The mold compound may be an epoxy such as for example that available from Sumitomo Corp. and Nitto Denko Corp., both having headquarters in Japan. Other mold compounds from other manufacturers are contemplated. The mold compound may be applied according to various known processes, including by transfer molding or injection molding techniques.

After the integrated circuit assemblies 110 on the panel are encapsulated in step 220, the respective assemblies may be singulated in step 222 from the panel to form the finished integrated circuit assembly 110 shown in FIG. 5. Each integrated circuit assembly 110 may be singulated by any of a variety of cutting methods including sawing, water jet cutting, laser cutting, water guided laser cutting, dry media cutting, and diamond coating wire cutting. Once cut into assemblies 110, the assemblies may be tested in a step 224 to determine whether they are functioning properly. As is known in the art, such testing may include electrical testing, burn in and other tests. In step 226, the finished integrated circuit assembly 110 may be encased within the lid 112 shown in FIG. 4.

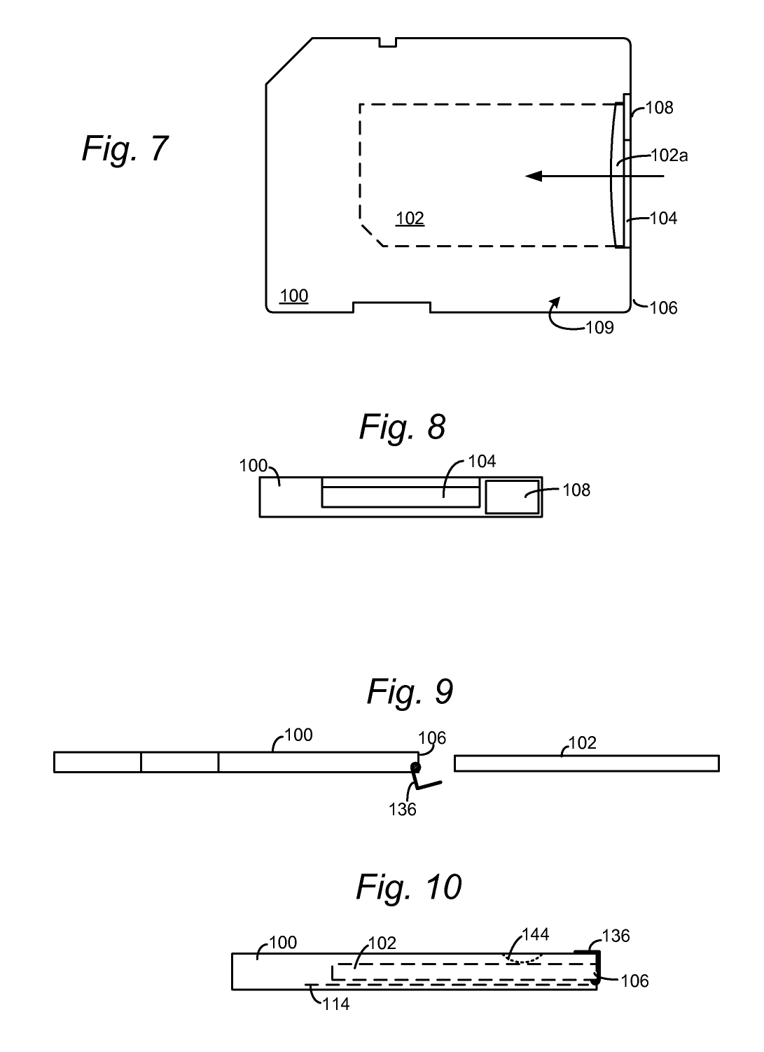

The operation of an embodiment of the present invention will now be described with reference to FIGS. 7-13. As seen in FIGS. 7 and 8, a MegaSIM card 102 is inserted into slot 104 within rear edge 106 in MegaSIM adapter 100. In embodiments, the card 102 may fit entirely within adapter 100. However, a rear portion of card 102 may remain protruding from the rear surface 106 of adapter 100 when card 102 is fully seated within adapter 100 in alternative embodiments. Slot 104 may be open at a top surface 109 of adapter 100, and extend inward a short distance on top surface 109 from rear surface 106. In embodiments where the card 102 fits fully within the adapter 100, a rear portion of the card 102a remains exposed in the open top portion of slot 104 and may be grasped to remove the card from the MegaSIM adapter slot 104. When the card 102 is fully inserted within the adapter slot 104, the slide 108 may be moved from its retracted position shown in FIGS. 4 and 8 to its locking position shown in FIG. 7 to lock the card 102 within the slot 104.

It is understood that a wide variety of locking mechanisms may be provided in alternative embodiments. For example, as shown in FIGS. 8 and 9, the rear surface 106 of adapter 100 may include a hinged cap 136. After the MegaSIM card 102 is fully inserted within the adapter 100 as shown in FIG. 9, the cap 136 may be latched in a closed position as shown in FIG. 9 to seal the card 102 within the adapter 100. In a further embodiment (not shown) a spring loaded “push-push” mechanism may be provided within adapter 100 as is known in the art so that a card 102 may be locked within the adapter 100 upon initial insertion, and thereafter, pushing on the back end of card 102 may disengage it from the adapter slot 104. In further embodiments, the MegaSIM adapter 100 may operate without slide 108, cap 136 or any other locking mechanism, and card 102 may be retained within the adapter slot 104 solely by the forces of friction of the card 102 against the sides of the adapter slot 104.

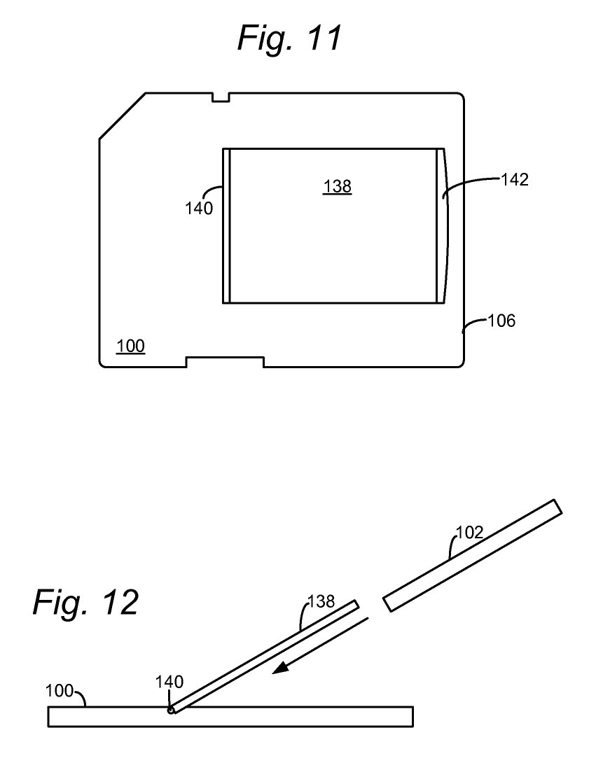

An alternative embodiment of SIM adapter 100 is shown in FIGS. 11 and 12. In FIGS. 11 and 12, slot 104 may be omitted from rear edge 106 in favor of a MegaSIM card acceptor door 138. Door 138 includes a rear portion (distal from rear edge 106) pivotally mounted to top surface 109 of adapter 100 via a hinge 140. A front section of door 138 may include a slot 142 allowing door 138 to be manually gripped and opened. In operation as shown in FIG. 12, door 138 may be manually opened and thereafter, card 102 may be inserted directly into the adapter 100 so that the connector on card 102 is pressed down into engagement with connector 122 on integrated circuit assembly 110.

In embodiments, door 138 may include a pair of side rails spaced apart a distance to receive the MegaSIM card 102 therebetween. The card 102 may be inserted into the pair of side rails within the door 138 and thereafter, door 138 may be closed to bring a connector on card 102 into contact with connector 122 on substrate 114. Alternatively, the side rails may be omitted and, when door 138 is open, the card 102 may fit within an appropriately sized opening in adapter 100 made accessible by the opening of door 138. Door 138 may be biased to a closed position as by a spring wound around hinge 140. Alternatively or additionally, the door 138 may snap fit into detents within the surface of adapter 100 adjacent door 138 to hold the door closed.

The opening within the interior of adapter 100 for receiving the card 102 may have a height approximately equal to a height of the card to ensure a snug fit of the card within the adapter and good contact of the card 102 connector against connector 122 on substrate 114. Alternatively or additionally, any of the embodiments described herein may include a leaf spring 144 (FIG. 10) or the like mounted on an upper interior surface of the adapter opposite the connector 122. The spring 144 biases the card against connector 122 to ensure good contact of the card 102 connector against connector 122 when the MegaSIM card 102 is fully inserted.

Exchange of data between a host device and MegaSIM card 102 through adapter 100 will now be explained with reference to the block diagram of FIG. 13. Once MegaSIM card 102 is inserted within slot 104 or door 138, the adapter 100 allows the exchange of data between MegaSIM card 102 and a host device, such as for example a PC, digital camera, digital music player, video game console, PDA and/or cellular telephone. In the embodiment described with respect to FIGS. 4-13, MegaSIM adapter 100 adapts MegaSIM card 102 for use with an SD card slot in the host device. As explained hereinafter, the adapter 100 may adapt MegaSIM card 102 to other standard memory card formats.

FIG. 13 shows a block diagram of a MegaSIM card 102 seated within a MegaSIM card adapter 100. Many conventional adapters are provided to adapt memory cards of different sizes but operating by the same protocols, such as for example an adapter adapting a MicroSD card to work within an SD card slot. These adapters need only include an internal network of electrical traces and terminals to connect the contact fingers of the inserted card to the contact fingers of the adapter that mate with the electrical terminals within the host slot. However, MegaSIM card 102 operates by a different protocol than an SD card. Accordingly, integrated circuit assembly 110 is provided to transfer between the MegaSIM card 102 and SD card protocols.

In particular, integrated circuit assembly 110 includes USB host controller 130, SD controller 132 and MegaSIM adapter microcontroller 134 which together allow the exchange of information between MegaSIM card 102 and a host device when the adapter 100 is seated within an SD card slot of the host device. Each of controllers 130, 132 and 134 may include RAM for storing temporary variables, ROM for storing the chip operating system and a CPU to control chip function. Data may be exchanged to and from flash memory die 26 of MegaSIM card 102 via a high speed USB interface through USB controller 28 on MegaSIM card 102. Additionally, all ISO 7816 commands on MegaSIM card 102 can be tunneled through the USB controller 28 so that all communication to and from MegaSIM card 102 takes place over the high speed USB interface.

Where MegaSIM card 102 operates in this manner, all signals from MegaSIM card 102 are received in adapter 100 within a USB host interface of the USB host controller 130. These signals are then transferred to adapter microcontroller 134, which converts from USB protocols to SD protocols. The microcontroller 134 then transfers the SD formatted signals to the SD controller 132 for forwarding to the host device via the SD connector (contact fingers 124).

Similarly, all communication from the host device is received in adapter 100 within the SD connector 124 and transferred to an SD interface of SD controller 132. These signals are then transferred to adapter microcontroller 134, which converts from SD protocols to USB protocols. The microcontroller 134 then forwards the USB formatted signals to MegaSIM card 102 via USB host controller 130.

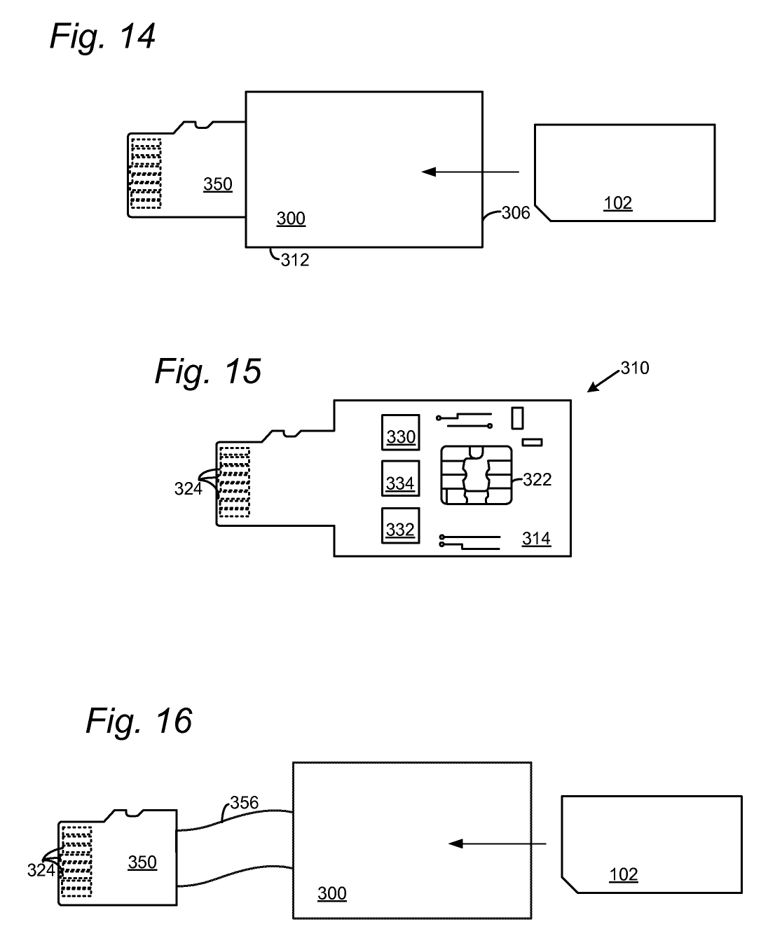

As indicated above, adapter 100 may be used to adapt a MegaSIM card to standards other than the SD standard. One additional embodiment is shown and described hereinafter with respect to FIGS. 14-22. In the embodiments of FIGS. 14-22, components which are the same as in the above-described embodiment of FIGS. 4-12 have reference numerals incremented by 200. Accordingly, FIG. 14 shows a MegaSIM adapter 300 including a MicroSD connector 350 for allowing the exchange of data between a MegaSIM card 102 and a host device (not shown) via the standard MicroSD card slot. Referring to FIG. 15, MegaSIM adapter 300 includes an integrated circuit assembly 310 formed on a substrate 314. Upon completion of fabrication of integrated circuit assembly 310, a portion of the substrate 314 may be encased within a lid 312 as shown in FIG. 14. However, an end of substrate 314 may be formed in the shape of a MicroSD card and include contact pads 324 formed according to the MicroSD standard. This portion of the substrate may be encapsulated along with the rest of the substrate but may protrude from lid 312 upon completion of adapter 300 fabrication to provide the connector 350.

In operation, the connector 350 may be received within a MicroSD card slot, with the lidded portion 312 protruding from the MicroSD slot. MegaSIM card 102 may be inserted into a slot at the distal end 306 of adapter 300. Alternatively, MegaSIM adapter 300 may include a door in an upper surface of the adapter as described above with respect to FIGS. 11 and 12. Card 102 may be inserted so that the connector on card 102 mates with the connector 322 on substrate 314 to allow the exchange of data between MegaSIM card 102 and the host device. A portion of the MegaSIM card 102 may protrude from the rear edge 306 of the adapter 300. Alternatively, the adapter 300 may be large enough so that the entire card 102 fits within the adapter 300. Adapter 300 may include a slide or cap at its rear edge 306 as described above for locking the card 102 within the adapter 300 in embodiments where the card 102 fits entirely within the adapter 300.

In the embodiments shown in FIGS. 14 and 15, the MicroSD connector 350 is integrally formed on substrate 314 and is rigidly affixed to lid 312. In an alternative embodiment shown in FIG. 16, the connector 350 may be separate from substrate 314. In this embodiment, electrical signals may be transferred between contact fingers 324 on connector 350 and integrated circuit 310 on substrate 314 via a flex cable 356. Flex cable 356 may provide greater flexibility for the use of adapter 300 and may allow adapter 300 to be used in applications where connector 350 is used within a sealed compartment.

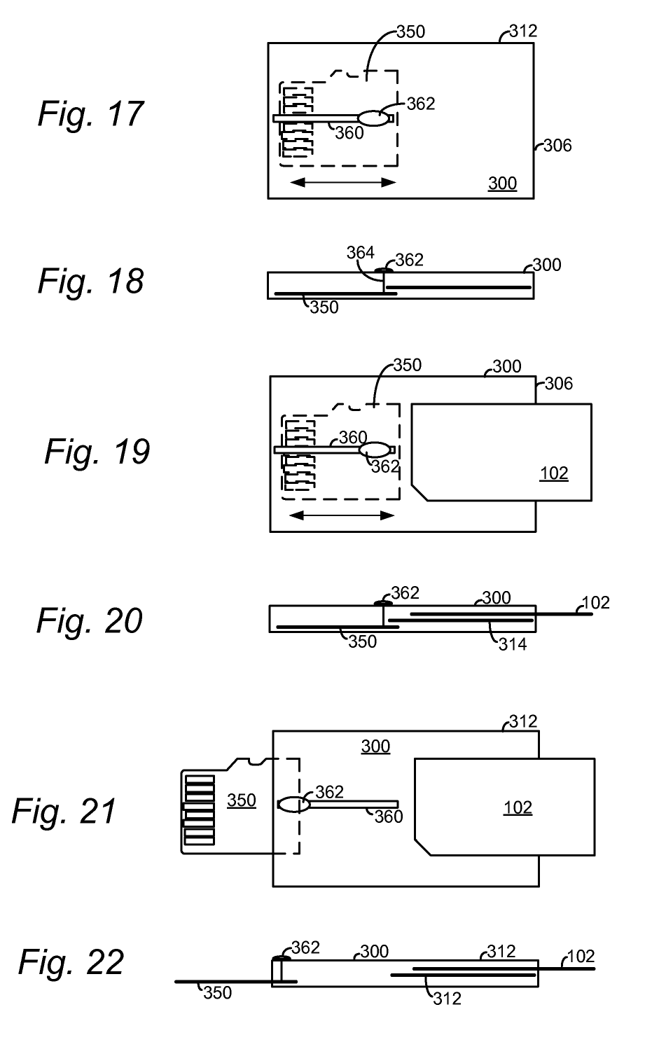

A further embodiment of MegaSIM adapter 300 used with a MicroSD card slot is shown in the embodiment of FIGS. 17-22. In that embodiment, the MicroSD connector 350 is moveable between a first position retracted within the lid 312 and a second position where it is extended to allow connection within a MicroSD card slot of a host device. Referring initially to FIGS. 17 and 18, there are shown top and cross sectional edge views of the MegaSIM adapter 300 with the MicroSD connector 350 in a retracted position. In the embodiment of FIGS. 17-22, a front portion of lid 312 may be formed with a slot 360. A finger grip 362 may further be provided to ride within slot 360 upon manual actuation by a user. Finger grip 362 may be fixedly mounted to the connector 350 via a post 364 seen for example in FIG. 18. The connector 350 may be affixed to the finger grip 362 by other means.

In operation, a MegaSIM card 102 may be inserted within a slot formed in the rear surface 306 of MegaSIM adapter 300. The card may protrude out of the rear surface 306, or adapter 300 may be large enough so that the entire card 102 fits within adapter 300. Card 102 may be inserted into adapter 300 with the connector 350 retracted as shown in FIGS. 19 and 20. Alternatively, the card 102 may be inserted within adapter 300 when the connector is in the extended position.

As shown in FIGS. 21 and 22, finger grip 362 may be manually actuated by a user to slide the finger grip from its rear position within slot 360 shown in FIGS. 17-20 to its forward position shown in FIGS. 21 and 22. As the connector 350 is rigidly connected to finger grip 362 via post 364, advancing finger grip 362 within slot 360 moves the connector from its retracted position to its extended position shown in FIGS. 21 and 22. In its extended position, connector 350 may seat within a MicroSD slot of a host device. Lid 312 and MegaSIM card 102 remain outside of the MicroSD slot.

In order to allow transfer of electrical signals from contact fingers 324 of retractable connector 350 and integrated circuit 310 on substrate 314, a ribbon cable may be provided between the connector 350 and substrate 314 within lid 312. Other methods of electrically connecting connector 350 to integrated circuit 310 when connector 350 is in its extended position are known in the art. For example, a forward portion of the adapter (opposite rear edge 306) may include electrical contacts that are electrically coupled to integrated circuit 310. The rear end of connector 350 may similarly include contacts which mate with the contacts in the forward portion of the adapter when the connector 350 is in its extended position. Other schemes are contemplated for electrically coupling connector 350 to the integrated circuit 310 upon extension of the connector 350.

While MegaSIM adapters have been described above for use in an SD and MicroSD card slot, other standard card configurations are contemplated. For example, the MegaSIM adapter may be configured to operate in MMC and M2 (Memory Stick Micro) card slots. The MegaSIM adapter may also operate with a Serial ATA (Serial Advanced Technology Attachment) bus. In each of the above-described embodiments, the MegaSIM adapter allows widespread use of a MegaSIM card within a variety of standard card slots. In addition to transferring audio, video, photographs and other multimedia and application files, the adapter allows a user to easily copy subscriber data to a new mobile phone or device, or to backup subscriber information to a permanent storage device.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of transferring data between a host device and a MegaSIM card via a host device card slot having an interface transferring signals by a first protocol, the method comprising the steps of:
(a) inserting the MegaSIM card at least partially into an adapter with a connector of the MegaSIM card lying in contact with a first connector in the adapter;
(b) inserting the adapter at least partially into the card slot of the host device with a second connector of the adapter lying in contact with a connector in the card slot;
(c) receiving a first set of signals from the host device in the adapter by the first protocol;
(d) transferring from the first protocol to a second protocol used by an interface of the MegaSIM card to transfer signals; and
(e) transmitting the first set of signals from the adapter to the MegaSIM card by the second protocol.

2. A method as recited in claim 1, further comprising the steps of:
(f) receiving a second set of signals from the MegaSIM card in the adapter by the second protocol;
(g) transferring from the second protocol to the first protocol; and
(h) transmitting the second set of signals from the adapter to the host device card slot by the first protocol.

3. A method as recited in claim 1, wherein said step (c) of receiving the first set of signals from the host device in the adapter by the first protocol comprises the step of receiving the first set of signals from the host device in the adapter by the SD protocol.

4. A method as recited in claim 1, wherein said step (c) of receiving the first set of signals from the host device in the adapter by the first protocol comprises the step of receiving the first set of signals from the host device in the adapter by one of the Memory Stick Micro protocol, the MultiMedia Card protocol, or serial ATA.

5. A method as recited in claim 1, wherein said step (a) of inserting the MegaSIM card at least partially into an adapter comprises the step of fully inserting the MegaSIM card into the adapter.

6. A method as recited in claim 5, further comprising the step of locking the MegaSIM card within the adapter.

7. A method as recited in claim 5, wherein said step (a) of fully inserting the MegaSIM card into the adapter comprises the step of inserting the MegaSIM card into a slot at a rear face of the adapter.

8. A method as recited in claim 5, wherein said step (a) of fully inserting the MegaSIM card into the adapter comprises the step of inserting the MegaSIM card into a door which opens from a top surface of the adapter.

9. A method as recited in claim 5, wherein said step (b) of inserting the adapter at least partially into the card slot of the host device with a second connector of the adapter lying in contact with a connector in the card slot comprises the step of inserting the adapter into an SD card slot with contact fingers of the adapter lying in contact with terminals in the card slot.

10. A method as recited in claim 5, wherein said step (b) of inserting the adapter at least partially into the card slot of the host device with a second connector of the adapter lying in contact with a connector in the card slot comprises the step of inserting at least a portion of the adapter into a MicroSD card slot with contact fingers of the adapter lying in contact with terminals in the card slot.

11. A method as recited in claim 10, wherein said step (b) of inserting the adapter at least partially into the card slot of the host device comprises inserting a connector shaped like a MicroSD card into the card slot, the connector rigidly affixed to remaining portions of the adapter.

12. A method as recited in claim 10, wherein said step (b) of inserting the adapter at least partially into the card slot of the host device comprises inserting a connector shaped like a MicroSD card into the card slot, the connector flexibly affixed to remaining portions of the adapter.

13. A method as recited in claim 10, wherein said step (b) of inserting the adapter at least partially into the card slot of the host device comprises inserting a connector shaped like a MicroSD card into the card slot, the connector moving between a first position within the adapter and a second position protruding from the adapter.

14. A method of transferring data between a host device and a MegaSIM card via a host device card slot having an interface for receiving an SD card, the method comprising the steps of:
(a) inserting the MegaSIM card at least partially into an adapter sized and shaped like an SD card, with a connector of the MegaSIM card lying in contact with a connector in the adapter;
(b) inserting the adapter into the card slot of the host device with contact fingers of the adapter lying in contact with terminals in the card slot;
(c) receiving a first set of signals from the host device in the adapter using SD protocols; and
(d) transmitting the first set of signals from the adapter to the MegaSIM card using USB protocols.

15. A method as recited in claim 14, further comprising the steps of:
(e) receiving a second set of signals from the MegaSIM card in the adapter using USB protocols; and
(f) transmitting the second set of signals from the adapter to the host device card slot using SD protocols.

16. A method as recited in claim 14, wherein said step (a) of inserting the MegaSIM card at least partially into an adapter comprises the step of fully inserting the MegaSIM card into the adapter.

17. A method as recited in claim 16, further comprising the step of locking the MegaSIM card within the adapter.

18. A method as recited in claim 16, wherein said step (a) of fully inserting the MegaSIM card into the adapter comprises the step of inserting the MegaSIM card into a slot at a rear face of the adapter.

19. A method as recited in claim 16, wherein said step (a) of fully inserting the MegaSIM card into the adapter comprises the step of inserting the MegaSIM card into a door which opens from a top surface of the adapter.

20. A method of transferring data between a host device and a MegaSIM card via a host device card slot having an interface for receiving a MicroSD card, the method comprising the steps of:
(a) inserting the MegaSIM card at least partially into an adapter, the adapter including a first connector for mating with a connector of the MegaSIM card and a second connector shaped like a MicroSD card for mating within the host device card slot;
(b) inserting the second connector of the adapter into the card slot of the host device with contact fingers of the second connector lying in contact with terminals in the card slot;
(c) receiving a first set of signals from the host device in the adapter using SD protocols; and
(d) transmitting the first set of signals from the adapter to the MegaSIM card using USB protocols.

21. A method as recited in claim 20, further comprising the steps of:
(e) receiving a second set of signals from the MegaSIM card in the adapter using USB protocols; and
(f) transmitting the second set of signals from the adapter to the host device card slot using SD protocols.

22. A method as recited in claim 20, wherein said step (b) of inserting the second connector of the adapter into the card slot comprises the step of inserting a connector rigidly attached to the remaining portions of the adapter into the card slot.

23. A method as recited in claim 20, wherein said step (b) of inserting the second connector of the adapter into the card slot comprises the step of inserting a connector that is flexibly affixed to the remaining portions of the adapter.

24. A method as recited in claim 20, wherein said step (b) of inserting the second connector of the adapter into the card slot comprises the step of inserting a connector that is capable of moving between a first position within the adapter and a second position protruding from the adapter.

25. An adapter for adapting a MegaSIM card for use in one of an SD card slot or a MicroSD card slot of a host device, the adapter including:
a lid;
an opening formed in the lid for receiving the MegaSIM card at least partially within the lid;
a USB interface for receiving signals from the MegaSIM card for forwarding to the host device;
an SD interface for receiving signals from the host device for forwarding to the MegaSIM card; and
a microcontroller within the lid for receiving a first set of signals in a USB protocol format and transferring the first set of signals in an SD protocol format, and for receiving a second set of signals in an SD protocol format and transferring the second set of signals in a USB protocol format.

26. An adapter as recited in claim 25, wherein the opening is a slot at a rear surface of the adapter.

27. An adapter as recited in claim 26, further comprising a sliding latch for locking the MegaSIM card within the slot.

28. An adapter as recited in claim 26, further comprising a rotating cap for locking the MegaSIM card within the slot.

29. An adapter as recited in claim 25, further comprising a door in a major planar surface of the lid, the door capable of moving between a first position where the opening for receiving the MegaSIM card is exposed and a second position where the opening for receiving the MegaSIM card is sealed.

30. An adapter as recited in claim 25, wherein the lid is sized and shaped like an SD card.

31. An adapter as recited in claim 30, wherein the lid is capable of fitting completely within the SD card slot of the host device.

32. An adapter as recited in claim 30, wherein the lid fits only partially within the SD card slot of the host device.

33. An adapter as recited in claim 25, wherein the adapter includes a connector sized and shaped like a MicroSD card, the connector capable of mating within the MicroSD card slot.

34. An adapter as recited in claim 33, wherein the connector is stationary with respect to the lid.

35. An adapter as recited in claim 33, wherein the connector is flexibly mounted to the lid via a flex cable capable of transferring electrical signals.

36. An adapter as recited in claim 33, wherein the connector is capable of moving between a retracted position within the lid and an extended position outside of the lid, the connector capable of mating within the MicroSD card slot of the host device when in the extended position.
